(19) United States
(12) Patent Application Publication
(10) Pub. No.: US 2025/0323112 A1
(43) Pub. Date: Oct. 16, 2025

(54) MULTIPLE-STACK MEMORY SYSTEM WITH INTEGRATED COOLING UNIT

(71) Applicant: Micron Technology, Inc., Boise, ID (US)

(72) Inventors: Bhumika Chhabra, Boise, ID (US); Congcong Wang, Boise, ID (US); Yixin Yan, Boise, ID (US); Fatma Arzum Simsek-Ege, Boise, ID (US)

(21) Appl. No.: 19/085,509

(22) Filed: Mar. 20, 2025

Related U.S. Application Data
(60) Provisional application No. 63/634,335, filed on Apr. 15, 2024.

(51) Int. Cl. H01L 23/367; H01L 23/00; H01L 23/34; H01L 23/373; H01L 23/538; H01L 25/18; H10B 80/00; H10D 80/30

(52) U.S. Cl. CPC H01L 23/367; H01L 23/34; H01L 23/5385; H01L 24/08; H01L 25/18; H10B 80/00; H10D 80/30; H01L 23/3735; H01L 24/16; H01L 2224/08145; H01L 2224/08245; H01L 2224/16225; H01L 2924/1431; H01L 2924/1432; H01L 2924/1436; H01L 2924/1437

(57) ABSTRACT

Methods, systems, and devices for multiple-stack memory system with integrated cooling unit are described. A multiple-stack memory system may include a first memory device that comprises a first logic die and a first stack of memory dies. The multiple-stack memory system may include a second memory device that comprises a second logic die and a second stack of memory dies. A cooling unit of the multiple-stack memory system may be coupled with a bottom memory die of the first stack of memory dies and coupled with a top memory die of the second stack of memory dies.

### CROSS REFERENCE

The present Application for Patent claims priority to U.S. Patent Application No. 63/634,335 by Chhabra et al., entitled “MULTIPLE-STACK MEMORY SYSTEM WITH INTEGRATED COOLING UNIT,” filed Apr. 15, 2024, which is assigned to the assignee hereof, and which is expressly incorporated by reference in its entirety herein.

### TECHNICAL FIELD

The following relates to one or more systems for memory, including a multiple-stack memory system with an integrated cooling unit.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports multiple-stack memory system with integrated cooling unit in accordance with examples as disclosed herein.

FIG. 2 shows an example of a system that supports multiple-stack memory system with integrated cooling unit in accordance with examples as disclosed herein.

FIG. 3 shows an example of a multiple-stack memory system with an integrated cooling unit in accordance with examples as disclosed herein.

FIG. 4 shows an example of a memory die at a stage of manufacturing in accordance with examples as disclosed herein.

FIG. 5 shows an example of a memory die at a stage of manufacturing in accordance with examples as disclosed herein.

FIG. 6 shows an example of a memory die at a stage of manufacturing in accordance with examples as disclosed herein.

FIG. 7 shows an example of a multiple-stack memory system at a stage of manufacturing in accordance with examples as disclosed herein.

FIG. 8 shows an example of a multiple-stack memory system at a stage of manufacturing in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be referred to as a stacked memory system or memory stack and may be implemented as part of a high bandwidth memory (HBM) system or a coupled dynamic random access memory (DRAM) system, among other examples, and may support solutions for memory-centric logic, such as graphics processing units (GPUs), among other implementations.

In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Improved stacked memory systems may be desired. According to the techniques and designs described herein, several stacked memory systems may be combined to form a multiple-stack memory system. For example, a first HBM system may be stacked on a second HBM system to provide increased functionality (e.g., increased channel quantity, increased bandwidth, increased memory capacity) relative to single-stack memory systems. The multiple-stack memory system may be formed using hybrid bonding techniques, which may reduce the form factor of the multiple-stack memory system relative to other techniques. But the multiple-stack memory system may generate and retain more heat compared to single-stack memory systems, a phenomenon which may negatively impact the performance of the multiple-stack memory system. According to the techniques and designs described herein, a cooling unit may be disposed between the memory stacks that form a multiple-stack memory system so that heat is dissipated within the multiple-stack memory system.

In addition to applicability in memory systems as described herein, techniques for multiple-stack memory systems featuring integrated cooling units may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving heat dissipation, which may increase reliability, among other benefits.

In addition to applicability in memory systems as described herein, techniques for multiple-stack memory systems featuring integrated cooling units may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving heat dissipation, which may extend the life of electronic devices and thereby reduce electronic waste), among other benefits.

Features of the disclosure are illustrated and described in the context of systems and architectures. Features of the disclosure are further illustrated and described in the context of device diagrams.

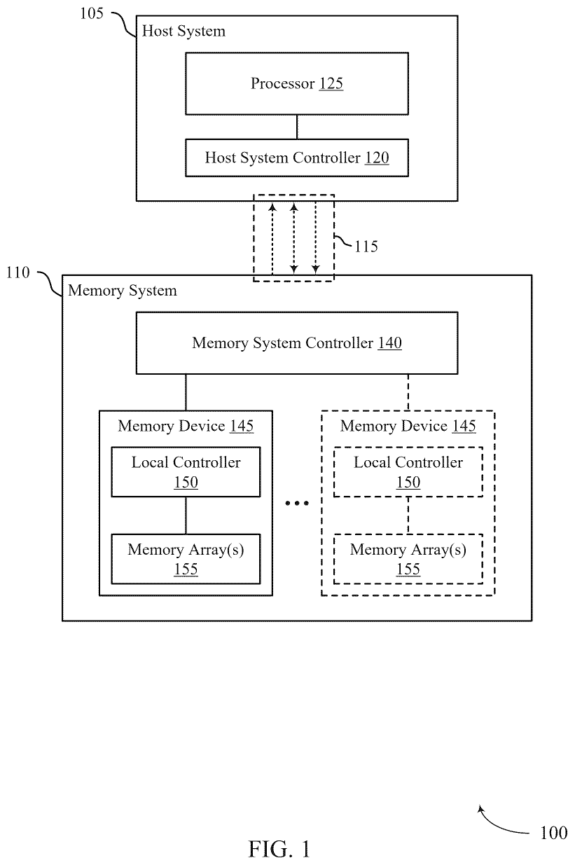

FIG. 1 shows an example of a system 100 that supports multiple-stack memory system with integrated cooling unit in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies. In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

According to the techniques and designs described herein, multiple systems 100 (which may be stacked memory systems) may be stacked to form a multiple-stack memory system that has improved functionality (e.g., increased channel quantity, increased bandwidth, increased memory capacity) relative to single-stack memory systems that include a single system 100. To compensate for the additional heat generated by the multiple-stack memory system, the multiple-stack memory system may include a cooling unit “sandwiched” between the stacked memory systems that form the multiple-stack memory system. Disposition of the cooling unit between the stacked memory systems (as opposed to elsewhere in the multiple-stack memory system) may free-up space in other areas of the multiple-stack memory system, reduce the footprint of the multiple-stack memory system, and/or improve the heat dissipation properties of the cooling unit (e.g., provide more uniform heat dissipate), among other advantages.

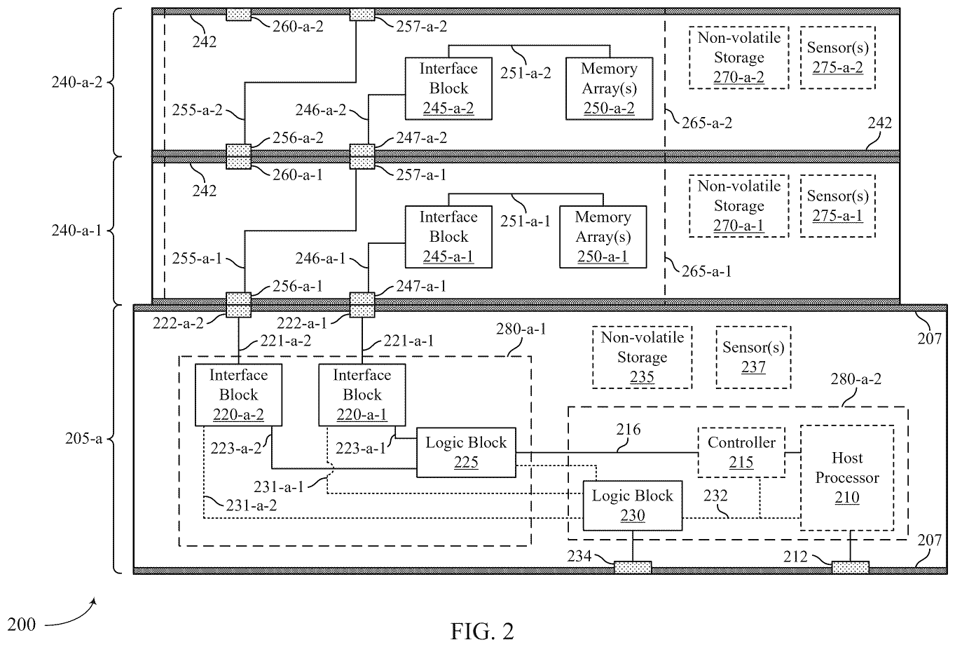

FIG. 2 shows an example of a system 200 (e.g., a semiconductor system, a system of coupled semiconductor dies, an HBM system, a 3D stacked memory system) that supports multiple-stack memory system with integrated cooling unit in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub- system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory system implementations), a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory system implementation) (e.g., in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In some examples, the system 200 may be part of a multiple-stack memory system as described herein. For example, the system 200 may be stacked below (or above) another stacked memory system similar to the system 200. To improve heat dissipation through the multiple-stack memory system, the multiple-stack memory system may include a cooling unit between the system 200 and the other stacked memory system. Improved heat dissipation may improve the reliability and endurance of the multiple-stack memory system, among other advantages.

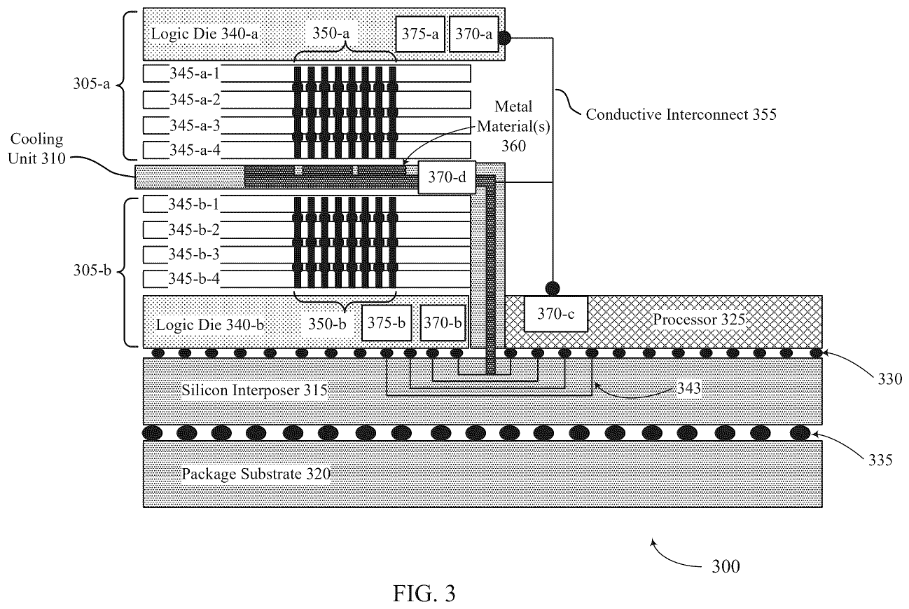

FIG. 3 shows an example of a multiple-stack memory system 300 that supports an integrated cooling unit in accordance with examples as disclosed herein. The multiple-stack memory system 300 may include a stacked memory system 305-a and a stacked memory system 305-b, which may be examples of a system 100 or a system 200 as described herein. The stacked memory systems 305 may be coupled with a cooling unit 310. The multiple-stack memory system 300 may be formed using hybrid bonding techniques, among other potential bonding techniques. Although shown with four memory dies per stacked memory system, there may be any quantity of memory dies per stacked memory system (e.g., 1, 2, 6, 8, 10, 12).

The multiple-stack memory system 300 may include a silicon interposer 315 upon which the stacked memory system 305-b is disposed, and a package substrate 320 upon which the silicon interposer 315 is disposed. The silicon interposer 315 may be coupled with the stacked memory system 305-b and the processor 325 through (e.g., via) conductive bumps 330 and may be coupled with the package substrate through (e.g., via) the conductive bumps 335. The conductive bumps may convey electrical signals that are propagated through channels (e.g., redistribution layers (RDLs)) such as the channels 343. A channel may refer to a conductive path that is capable of conveying electrical signals between components coupled with the channel.

The stacked memory system 305-a may include memory dies 345-a and a logic die 340-a that is configured to control and access the memory dies 345-a (e.g., responsive to commands from the processor 325). The logic die 340-a and the memory dies 345-a may exchange information (e.g., control signals, data signals) through channels that include the through-silicon-vias (TSVs) 350-a. The logic die 430-a and the processor 325 may exchange information (e.g., control signals, data signals) through channels that include the conductive interconnect 355. The conductive interconnect 355 may be external to the stacked memory systems 305 (e.g., as shown) or may be internal to (e.g., extend through, traverse through) the stacked memory system 305. The memory dies 345-a may be any type of memory dies such as DRAM dies, SRAM dies, or a combination thereof. In some examples, the memory die 345-a-1 and the memory die 345-a-2 may be SRAM dies (e.g., that serve as caches), and the rest of the memory dies 345 may be DRAM dies. Such a configuration may reduce latency, power consumption, or both relative to designs that exclusively use DRAM dies.

The stacked memory system 305-b may include memory dies 345-b and a logic die 340-b that is configured to control and access the memory dies 345-b (e.g., responsive to commands from the processor 325). The logic die 340-b and the memory dies 345-b may exchange information (e.g., control signals, data signals) through channels that include the through-silicon-vias (TSVs) 350-b. The logic die 430-b and the processor 325 may exchange information (e.g., control signals, data signals) through channels that include the conductive interconnect 355.

The cooling unit 310 may be configured to dissipate heat (e.g., by sinking heat to the silicon interposer 315) and may disposed between the stacked memory system 305-a and the stacked memory system 305-b. For example, the cooling unit 310 may be coupled with the memory die 345-a-4 (e.g., the bottom memory die, the memory die farthest from the logic die 340-a) of the stacked memory system 305-a and may be coupled with the memory die 345-b-1 (e.g., the top memory die, the memory die farthest from the logic die 340-b) of the stacked memory system 305-b. The cooling unit 310 may include one or more conductive metal material(s) 360 (e.g., highly thermal metal layers) configured as layers or lines. For example, the conductive metal material(s) 360 may include one or more layers or lines of copper, silver, or gold. The cooling unit 310 may be coupled with the silicon interposer 315 through a conductive interconnect 365. In some examples, the cooling unit 310 may be coupled with a logic block 370-d, which may control various aspects related to the cooling unit 310, exchange temperature information with other logic blocks 370, or both.

The cooling unit 310 may be coupled with one or more temperature sensors 375, which may be configured to detect temperature and to communicate temperature information to other components of the multiple-stack memory system 300. For example, the cooling unit 310 may be coupled with temperature sensor 375-a, which may be coupled with and potentially disposed within the logic die 340-a, and which may be configured to sense the temperature of the logic die 340-a. Additionally, or alternatively, the cooling unit 310 may be coupled with the temperature sensor 375-b, which may be coupled with and potentially disposed within the logic die 340-b, and which may be configured to sense the temperature of the logic die 340-b. In some examples, temperature information from the temperature sensor 375 may be used as a basis by another component to trigger (e.g., activate, enable) additional cooling measures (e.g., based on the temperature or temperature gradient exceeding a threshold temperature). A temperature sensor may also be referred to as a thermal sensor or other suitable terminology.

The cooling unit 310 may be coupled with one or more logic blocks 370, which may use temperature information (e.g., from a temperature sensor 375-a, from other logic blocks 370) to modify the operation of the multiple-stack memory system 300. For example, the cooling unit 310 may be coupled with logic block 370-a, which may use temperature information to modify the operation of the stacked memory system 305-a (e.g., the logic block 370-a may modify where data is stored within the memory dies 345-a, may modify the refresh rate of the memory dies 345-a, may modify channel utilization, may modify power magnitude and map). Additionally, or alternatively, the cooling unit 310 may be coupled with logic block 370-b, which may use temperature information to modify the operation of the stacked memory system 305-b (e.g., the logic block 370-b may modify where data is stored within the memory dies 345-b, may modify the refresh rate of the memory dies 345-b). Additionally, or alternatively, the cooling unit 310 may be coupled with the processor 325 (e.g., through the logic block 370-c), which may use temperature information to modify the operation of the multiple-stack memory system 300. Modification of the operation of the multiple-stack memory system 300 (e.g., by any of the logic blocks, logic dies, or processor) may be based on the temperature information indicating that the temperature of the multiple-stack memory system 300 satisfies (e.g., exceeds) a threshold temperature.

Thus, the cooling unit 310 may be positioned between the stacked memory system 305-a and the stacked memory system 305-b. Such positioning of the cooling unit 310 (as opposed to elsewhere in the multiple-stack memory system) may free-up space in other areas of the multiple-stack memory system, reduce the footprint of the multiple-stack memory system, and/or improve the heat dissipation properties of the cooling unit, among other advantages.

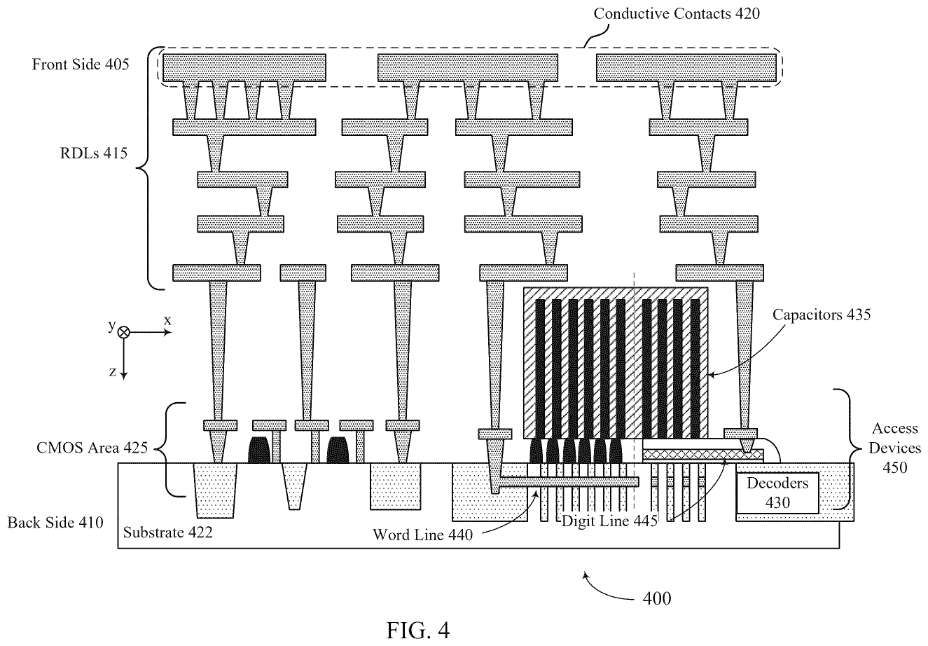

FIGS. 4 through 8 show various stages of manufacturing a multiple-stack memory system with an integrated cooling unit as described herein. The figures are illustrated relative to an x-y-z coordinate system that shows the x-direction, y-direction, and z-direction.

FIG. 4 shows an example of a memory die 400 at a stage of manufacturing in accordance with examples as disclosed herein. The memory die 400 may be an example of a memory die 345-a. For example, the memory die 400 may be the bottom memory die of the top memory stack of a multiple-stack memory system (e.g., memory die 400 may be an example of the memory die 345-a-4 described with reference to FIG. 3). The memory die 400 may be represented at a stage A of manufacturing a multiple-stack memory system before TSVs are added to the memory die 400. Thus, any of the structures illustrated in FIG. 4 may be formed before formation of the TSVs.

The memory die 400 may include a front side 405 which may be the side of the memory die 400 that is doped to form various components (e.g., in the CMOS area 425) of the memory die 400. The memory die 400 may also include a back side 410 which may be the side of the memory die that is opposite the front side 405.

The memory die 400 may include redistribution layers (RDLs), such as redistribution layers 415 (e.g., conductive interconnects) that are electrically coupled with a cooling unit at a later stage of manufacturing. The redistribution layers 415 may be formed before or as part of stage A and may be disposed within an insulative material such as an oxide. The redistribution layers 415 may include one or more conductive contacts 420 that are physically coupled (e.g., placed in direct contact with) with the cooling unit at the later stage of manufacturing. The redistribution layers 415 may be routed down to the CMOS area 425 within the substrate 422, which may include high voltage, high current CMOS circuitry. Two components may be referred to as being electrically coupled if current is capable of flowing between the two components. Two components may be referred to as being physically coupled if the two components are in direct contact with each other (e.g., are physically touching).

The memory die 400 may include a substrate 422 within which decoders 430 are disposed. The decoders 430 may be part of the access devices 450 used to access the array and may be coupled with the memory cells of the array (e.g., capacitors 435), one or more word lines 440 for the array, one or more digit lines 445 for the array, or any combination thereof.

Thus, after stage A of manufacturing a multiple stack memory system, the components illustrated in FIG. 4, including the redistribution layers 415 for coupling with the cooling unit, may be formed within the memory die 400.

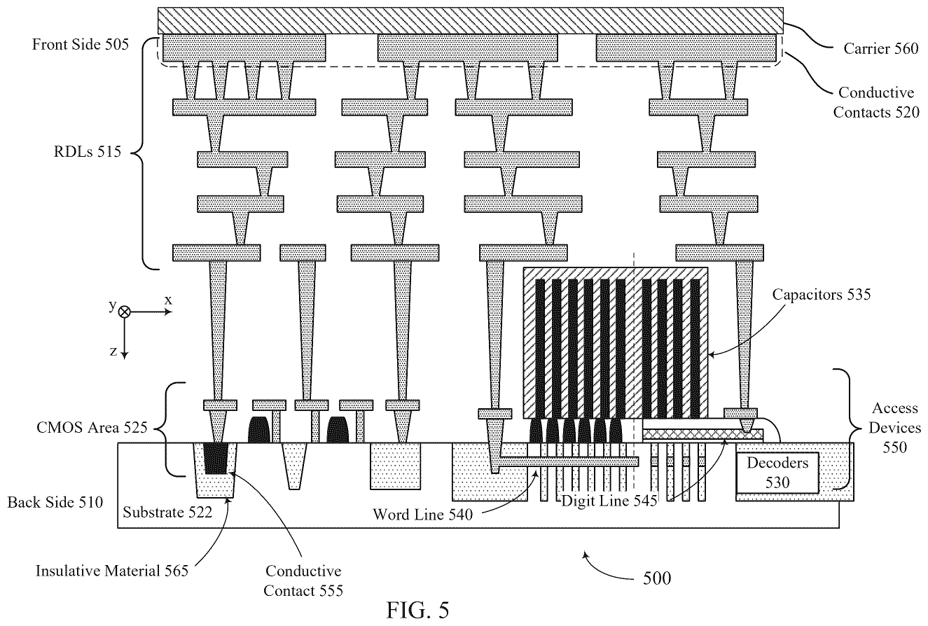

FIG. 5 shows an example of a memory die 500 at a stage of manufacturing in accordance with examples as disclosed herein. The memory die 500 may be an example of a memory die 345-b. For example, the memory die 500 may be the top memory die of the bottom memory stack of a multiple-stack memory system (e.g., memory die 500 may be an example of the memory die 345-b-1 described with reference to FIG. 3). The memory die 500 may be represented at a stage B of manufacturing a multiple-stack memory system before TSVs are added to the memory die 500. Thus, any of the structures illustrated in FIG. 5 may be formed before formation of the TSVs.

The memory die 500 may include a front side 505 which may be the side of the memory die 500 that is doped to form various components (e.g., in the CMOS area 525) of the memory die 500. The memory die 500 may also include a back side 510 which may be the side of the memory die that is opposite the front side 505. The memory die 500 may include a substrate 522 within which decoders 530 are disposed. The decoders 530 may be part of the access devices 550 used to access the array and may be coupled with the memory cells of the array (e.g., capacitors 535), one or more word lines 540 for the array, one or more digit lines 545 for the array, or any combination thereof.

The memory die 500 may include redistribution layers (RDLs), such as redistribution layers 515 (e.g., conductive interconnects). The redistribution layers 415 may be formed before or as part of stage B and may be disposed within an insulative material such as an oxide. The redistribution layers 515 may include one or more conductive contacts 520. The memory die 500 may also include one or more conductive contacts 555 (also referred to as conductive blocks) that are disposed within (e.g., embedded within) the substrate 522. In some examples, the conductive contact(s) 555 may be disposed within an insulative material 565. In some examples, the conductive contacts 555 may be formed before gate formation for the array and after silicon trench isolation formation (e.g., formation of the insulative material 565). So, the conductive contacts and trenches may be buried in isolation areas in which an isolated dielectric (e.g., insulative material 565) surrounds the conductive contacts. In some examples, the conductive contacts 555 may be coupled with high voltage transistors.

At a later stage of manufacturing, either the conductive contacts 520 or the conductive contact(s) 555 may be coupled with (e.g., physically coupled with) the cooling unit at the later stage of manufacturing. For example, in a front-to-front (F2F) configuration in which the front side 405 of the memory die 400 and the front side 505 of the memory die 500 are each coupled with the cooling unit, the conductive contacts 520 may be coupled with (e.g., physically coupled with) the cooling unit (and the conductive contact(s) 555 may be omitted). In a front-to-back (F2B) configuration in which the front side 405 of the memory die 400 and the back side 510 of the memory die 500 are each coupled with the cooling unit, the conductive contacts 555 may be coupled with (e.g., physically coupled with) the cooling unit (and the conductive contact(s) 520 may be omitted).

As part of stage B (e.g., in the case of an F2B configuration), a carrier material may be deposited on (e.g., formed on) the memory die 500 to form carrier 560. The carrier material may be deposited over (e.g., in contact with) the redistribution layers 515. Thus, the memory die 500 may be attached to a carrier material (e.g., carrier 560) after stage B. The carrier 560 may allow the memory die 500 to be placed on carrier wafer and inverted upside-down for a later stage of manufacturing.

In a variation of stage B (e.g., in the case of an F2F configuration), the cooling unit 575 (instead of the carrier 560) may be coupled with the memory die 500. For example, in the variation of stage B, the carrier 560 may be omitted and the cooling unit 575 may be coupled with (e.g., physically coupled with, electrically coupled with, or both) the conductive contacts 520.

Thus, after stage B of manufacturing the multiple stack memory system, the components illustrated in FIG. 5, including the conductive contacts 520, the conductive contact(s) 555, or both, may be formed within the memory die 500.

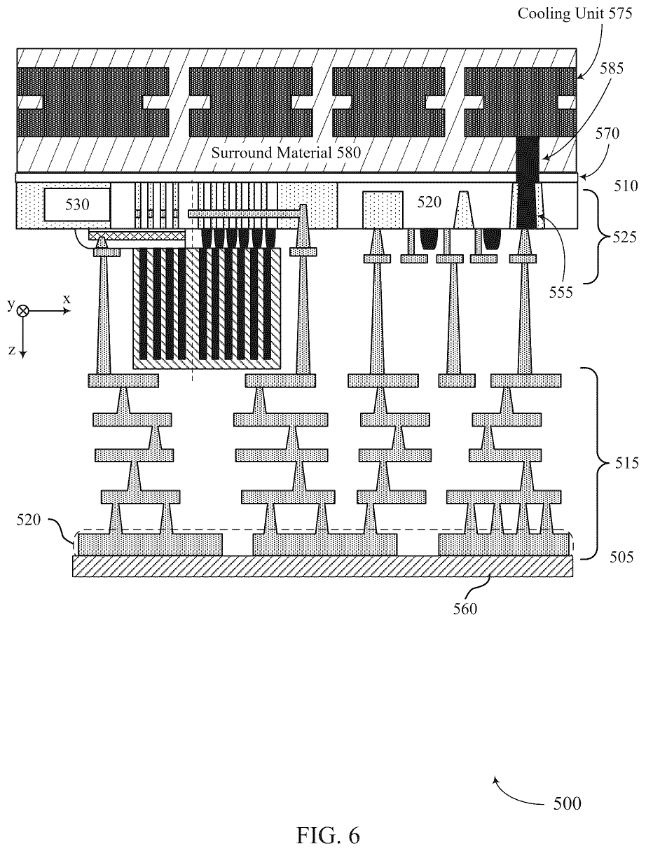

FIG. 6 shows an example of the memory die 500 at a stage of manufacturing in accordance with examples as disclosed herein. The memory die 500 may be represented at a stage C of manufacturing the multiple-stack memory system in an F2B configuration. Stage C may occur after stage B and may occur before TSVs are added to the memory die 500.

As part of stage C, the cooling unit 575 may be formed on (e.g., bonded with) the second memory die 500. In some examples, the cooling unit 575 may be formed on the second memory die 500 after removing silicon material (e.g., a portion of the substrate 522) to expose the conductive contact(s) 555.

The cooling unit 575 may include one or more metal materials at least partially disposed within a surround material 580. The surround material 580 may be coupled with an interface material 570, which in turn may be coupled with the substrate 522 of the memory die 500. The cooling unit 575 may be electrically coupled with the memory die 500 through the conductive contact 585 and the conductive contact 555. Accordingly, the cooling unit 575 may be coupled with the redistribution layers 515 through the conductive contact 585 and the conductive contact 555. So, the cooling unit 575 may be formed after formation of the interface material 570 (also referred to as block material) and after deposition of the surround material 580 (e.g., after dielectric oxide deposition).

Thus, after stage C of manufacturing the multiple stack memory system, the cooling unit 575 may be attached to (e.g., bonded with) the back side 510 of the memory die 500.

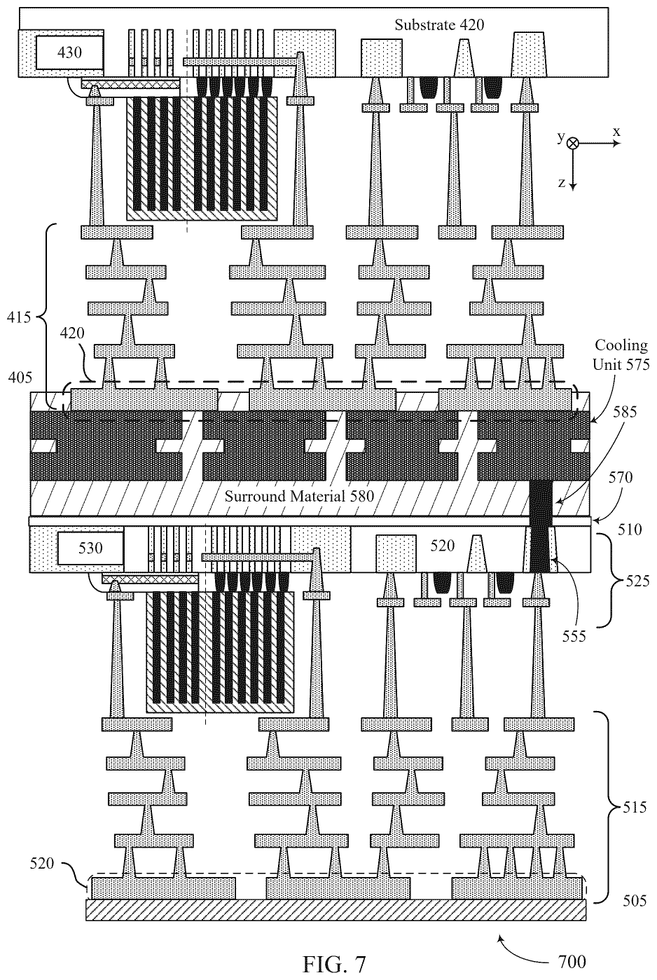

FIG. 7 shows an example of a multiple-stack memory system 700 at a stage of manufacturing in accordance with examples as disclosed herein. The multiple-stack memory system 700 may include the memory die 400, the memory die 500, and the cooling unit 575 as described with reference to FIGS. 4-6. The cooling unit 575 may be disposed between, and coupled with, the memory die 400 and the memory die 500, and may facilitate heat dissipation in the multiple-stack memory system 700. The multiple-stack memory system 700 may be represented at a stage D of manufacturing the multiple-stack memory system in an F2B configuration. Stage D may occur after stage C.

As part of stage D, the cooling unit 575 may be coupled with (e.g., bonded to) the memory die 400. For example, the cooling unit 575 may be coupled with (e.g., physically coupled with, electrically coupled with, or both) the conductive contacts 420 of the redistribution layers 415 of the memory die 400.

Thus, after stage D, the cooling unit 575 may be between, and coupled with, the memory die 400 (e.g., the front side 405 of the memory die 400) and the memory die 500 (e.g., the back side 510 of the memory die 500).

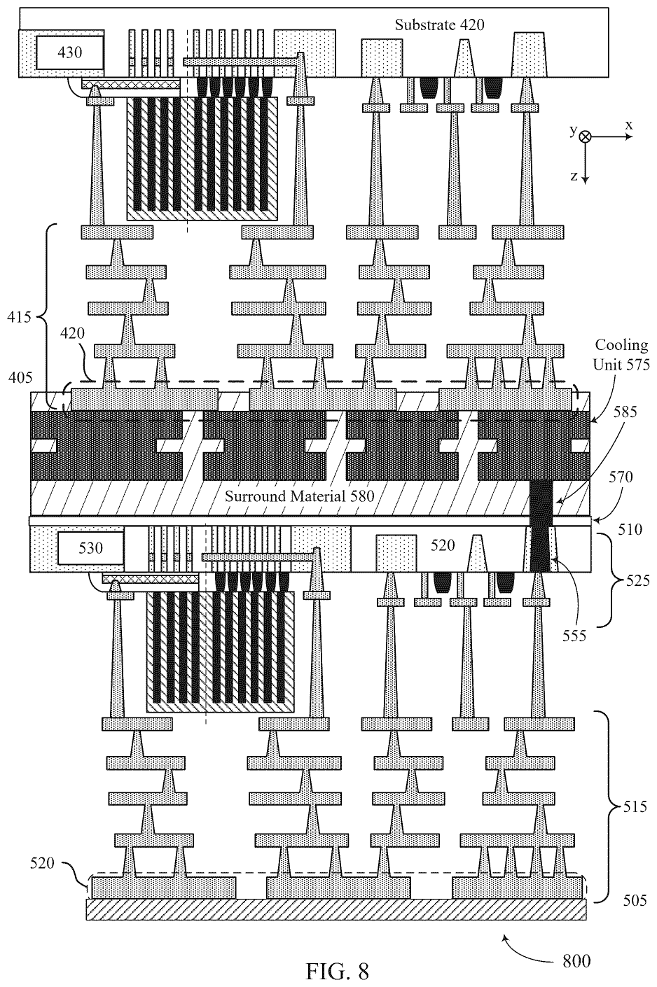

FIG. 8 shows an example of a multiple-stack memory system 800 at a stage of manufacturing in accordance with examples as disclosed herein. The multiple-stack memory system 800 may include the memory die 400, the memory die 500, and the cooling unit 575 as described with reference to FIGS. 4-6. The cooling unit 575 may be disposed between, and coupled with, the memory die 400 and the memory die 500, and may facilitate heat dissipation in the multiple-stack memory system 800.

The multiple-stack memory system 800 may be represented at a stage E of manufacturing the multiple-stack memory system in an F2F configuration. Stage E may occur after a variation of stage B, in which the cooling unit 575 (instead of the carrier 560) is coupled with the memory die 500. For example, in the variation of stage B, the cooling unit 575 may be coupled with (e.g., physically coupled with, electrically coupled with, or both) the conductive contacts 520.

As part of stage E, the cooling unit 575 may be coupled with (e.g., bonded to) the memory die 400. For example, the cooling unit 575 may be coupled with (e.g., physically coupled with, electrically coupled with, or both) the conductive contacts 420 of the redistribution layers 415 of the memory die 400.

Thus, after stage E, the cooling unit 575 may be between, and coupled with, the memory die 400 (e.g., the front side 405 of the memory die 400) and the memory die 500 (e.g., the front side 505 of the memory die 500).

Thus, a multiple-stack memory system may be manufactured. For example, according to the techniques described herein, formation of a multiple-stack memory system with an integrated cooling unit may include forming redistribution layers (e.g., RDLs 415) within a first memory die (e.g., memory die 400), the redistribution layers comprising one or more conductive contacts (e.g., conductive contacts 420). Formation may further include forming conductive contacts (e.g., conductive contacts 555) within a substrate (e.g., substrate 522) of a second memory die (e.g., memory die 500), the substrate comprising decoders (e.g., decoders 530) for access a memory array of the second memory die. Formation may further include forming a cooling unit on the second memory die, the cooling unit coupled with the conductive contacts within the second memory die. Formation may further include bonding the first memory die with the cooling unit such that the cooling unit is coupled with the conductive contacts within the first memory die.

In some examples, formation of the multiple-stack memory system includes forming a dielectric material (e.g., surround material 580) on the second memory die, wherein the cooling unit is formed within the dielectric material. In some examples, formation of the multiple-stack memory system includes attaching the second memory die to a carrier material (e.g., carrier 560), where the cooling unit is formed on the second memory die after attaching the second memory die to the carrier material. In some examples, formation of the multiple-stack memory system includes removing silicon material to expose the one or more conductive contacts of the second memory die, where the cooling unit is formed on the second memory die after removing the silicon material.

It should be noted that the aspects described herein describe possible implementations, and that the operations and the steps may be rearranged or otherwise modified and that other implementations are possible. Further, portions from two or more of the implementations may be combined.

An apparatus is described. The following provides an overview of aspects of the apparatus as described herein:

Aspect 1: An apparatus, including: a first memory device that includes a first logic die and a first stack of memory dies; a second memory device that includes a second logic die and a second stack of memory dies; and a cooling unit coupled with a bottom memory die of the first stack of memory dies and coupled with a top memory die of the second stack of memory dies.

Aspect 2: The apparatus of aspect 1, further including: a silicon interposer coupled with the second logic die and a processor; and a package substrate upon which the silicon interposer is stacked.

Aspect 3: The apparatus of aspect 2, where the second logic die and the processor are coupled with a first side of the silicon interposer, and the package substrate is coupled with a second side of the silicon interposer that is opposite of the first side.

Aspect 4: The apparatus of any of aspects 1 through 3, further including: a first temperature sensor coupled with the first logic die and the cooling unit and configured to sense a temperature of the first logic die.

Aspect 5: The apparatus of aspect 4, further including: a first logic block coupled with the first logic die and the first temperature sensor and configured to modify operations of the first stack of memory dies based at least in part on the temperature of the first logic die.

Aspect 6: The apparatus of any of aspects 4 through 5, further including: a second temperature sensor coupled with the second logic die and the cooling unit and configured to sense a temperature of the second logic die.

Aspect 7: The apparatus of aspect 6, further including: a second logic block coupled with the second logic die and the second temperature sensor and configured to modify operations of the second stack of memory dies based at least in part on the temperature of the second logic die.

Aspect 8: The apparatus of any of aspects 1 through 7, further including: a logical block between the first memory device and the second memory device and coupled with the cooling unit.

Aspect 9: The apparatus of any of aspects 1 through 8, where the first memory device includes one or more dynamic random-access memory (DRAM) dies and one or more static random-access memory (SRAM) dies.

An apparatus is described. The following provides an overview of aspects of the apparatus as described herein:

Aspect 10: An apparatus, including: a first memory die coupled with a first stack of memory dies that is between the first memory die and a first logic die, the first memory die including a first substrate within which decoders for a memory array of the first memory die are disposed; a second memory die coupled with a second stack of memory dies that is between the second memory die and a second logic die, the second memory die including a second substrate within which decoders for a memory array of the second memory die are disposed; and a cooling unit coupled with, and disposed between, the first memory die and the second memory die and including one or more conductive layers configured to dissipate heat, the cooling unit coupled with a redistribution layer (RDL) that is coupled with the first substrate, and coupled with a conductive block embedded in the second substrate of the second memory die.

Aspect 11: The apparatus of aspect 10, further including: a silicon interposer coupled with the second logic die and a processor; and a package substrate upon which the silicon interposer is stacked.

Aspect 12: The apparatus of aspect 11, where the second logic die and the processor are coupled with a first side of the silicon interposer, and the package substrate is coupled with a second side of the silicon interposer that is opposite of the first side.

Aspect 13: The apparatus of any of aspects 10 through 12, further including: a first temperature sensor coupled with the first logic die and the cooling unit and configured to sense a temperature of the first logic die.

Aspect 14: The apparatus of aspect 13, further including: a first logic block coupled with the first logic die and the first temperature sensor and configured to modify operations of the first stack of memory dies based at least in part on a temperature of the first logic die.

Aspect 15: The apparatus of aspect 14, where the first logic block is coupled with the first logic die through a conductive interconnect that is external to the first stack of memory dies.

Aspect 16: The apparatus of any of aspects 14 through 15, where the first logic block is coupled with the first logic die through a conductive interconnect that traverses through the first stack of memory dies.

Aspect 17: The apparatus of any of aspects 13 through 16, further including: a second temperature sensor coupled with the second logic die and the cooling unit and configured to sense a second temperature of the second logic die.

Aspect 18: The apparatus of aspect 17, further including: a second logic block coupled with the first logic die and the second temperature sensor and configured to modify operations of the second stack of memory dies based at least in part on a temperature of the second logic die.

Aspect 19: The apparatus of any of aspects 10 through 18, further including: a logical block between the first memory die and the second memory die and coupled with the cooling unit.

An apparatus is described. The following provides an overview of aspects of the apparatus as described herein:

Aspect 20: An apparatus, including: a first memory die coupled with a first stack of memory dies that is between the first memory die and a first logic die, the first memory die including a first substrate within which decoders for a memory array of the first memory die are disposed; a second memory die coupled with a second stack of memory dies that is between the second memory die and a second logic die, the second memory die including a second substrate within which decoders for a memory array of the second memory die are disposed; and a cooling unit coupled with, and disposed between, the first memory die and the second memory die and including one or more conductive layers configured to dissipate heat, the cooling unit coupled with a first redistribution layer (RDL) that is coupled with the first substrate, and coupled with a second RDL that is coupled with the second substrate.

Aspect 21: The apparatus of aspect 20, further including: a silicon interposer coupled with the second logic die and a processor; and a package substrate upon which the silicon interposer is stacked.

Aspect 22: The apparatus of aspect 21, where the second logic die and the processor are coupled with a first side of the silicon interposer, and the package substrate is coupled with a second side of the silicon interposer that is opposite of the first side.

Aspect 23: The apparatus of any of aspects 20 through 22, further including: a first temperature sensor coupled with the first logic die and the cooling unit and configured to sense a temperature of the first logic die.

Aspect 24: The apparatus of aspect 23, further including: a first logic block coupled with the first logic die and the first temperature sensor and configured to modify operations of the first stack of memory dies based at least in part on a temperature of the first logic die.

Aspect 25: The apparatus of aspect 24, where the first logic block is coupled with the first logic die through a conductive interconnect that is external to the first stack of memory dies.

Aspect 26: The apparatus of any of aspects 24 through 25, where the first logic block is coupled with the first logic die through a conductive interconnect that traverses through the first stack of memory dies.

Aspect 27: The apparatus of any of aspects 23 through 26, further including: a second temperature sensor coupled with the second logic die and the cooling unit and configured to sense a temperature of the second logic die.

Aspect 28: The apparatus of aspect 27, further including: a second logic block coupled with the first logic die and the second temperature sensor and configured to modify operations of the second stack of memory dies based at least in part on a temperature of the second logic die.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open- ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a first memory device that comprises a first logic die and a first stack of memory dies;
a second memory device that comprises a second logic die and a second stack of memory dies; and
a cooling unit coupled with a bottom memory die of the first stack of memory dies and coupled with a top memory die of the second stack of memory dies.

2. The apparatus of claim 1, further comprising:
a silicon interposer coupled with the second logic die and a processor; and
a package substrate upon which the silicon interposer is stacked.

3. The apparatus of claim 2, wherein the second logic die and the processor are coupled with a first side of the silicon interposer, and wherein the package substrate is coupled with a second side of the silicon interposer that is opposite of the first side.

4. The apparatus of claim 1, further comprising:
a first temperature sensor coupled with the first logic die and the cooling unit and configured to sense a temperature of the first logic die.

5. The apparatus of claim 4, further comprising:
a first logic block coupled with the first logic die and the first temperature sensor and configured to modify operations of the first stack of memory dies based at least in part on the temperature of the first logic die.

6. The apparatus of claim 4, further comprising:
a second temperature sensor coupled with the second logic die and the cooling unit and configured to sense a temperature of the second logic die.

7. The apparatus of claim 6, further comprising:
a second logic block coupled with the second logic die and the second temperature sensor and configured to modify operations of the second stack of memory dies based at least in part on the temperature of the second logic die.

8. The apparatus of claim 1, further comprising:
a logical block between the first memory device and the second memory device and coupled with the cooling unit.

9. The apparatus of claim 1, wherein the first memory device comprises one or more dynamic random-access memory (DRAM) dies and one or more static random-access memory (SRAM) dies.

10. An apparatus, comprising:
a first memory die coupled with a first stack of memory dies that is between the first memory die and a first logic die, the first memory die comprising a first substrate within which decoders for a memory array of the first memory die are disposed;
a second memory die coupled with a second stack of memory dies that is between the second memory die and a second logic die, the second memory die comprising a second substrate within which decoders for a memory array of the second memory die are disposed; and
a cooling unit coupled with, and disposed between, the first memory die and the second memory die and comprising one or more conductive layers configured to dissipate heat, the cooling unit coupled with a redistribution layer (RDL) that is coupled with the first substrate, and coupled with a conductive block embedded in the second substrate of the second memory die.

11. The apparatus of claim 10, further comprising:
a silicon interposer coupled with the second logic die and a processor; and
a package substrate upon which the silicon interposer is stacked.

12. The apparatus of claim 11, wherein the second logic die and the processor are coupled with a first side of the silicon interposer, and wherein the package substrate is coupled with a second side of the silicon interposer that is opposite of the first side.

13. The apparatus of claim 10, further comprising:
a first temperature sensor coupled with the first logic die and the cooling unit and configured to sense a temperature of the first logic die.

14. The apparatus of claim 13, further comprising:
a first logic block coupled with the first logic die and the first temperature sensor and configured to modify operations of the first stack of memory dies based at least in part on a temperature of the first logic die.

15. The apparatus of claim 14, wherein the first logic block is coupled with the first logic die through a conductive interconnect that is external to the first stack of memory dies.

16. The apparatus of claim 14, wherein the first logic block is coupled with the first logic die through a conductive interconnect that traverses through the first stack of memory dies.

17. The apparatus of claim 13, further comprising:
a second temperature sensor coupled with the second logic die and the cooling unit and configured to sense a second temperature of the second logic die.

18. The apparatus of claim 17, further comprising:
a second logic block coupled with the first logic die and the second temperature sensor and configured to modify operations of the second stack of memory dies based at least in part on a temperature of the second logic die.

19. The apparatus of claim 10, further comprising:
a logical block between the first memory die and the second memory die and coupled with the cooling unit.

20. An apparatus, comprising:
a first memory die coupled with a first stack of memory dies that is between the first memory die and a first logic die, the first memory die comprising a first substrate within which decoders for a memory array of the first memory die are disposed;
a second memory die coupled with a second stack of memory dies that is between the second memory die and a second logic die, the second memory die comprising a second substrate within which decoders for a memory array of the second memory die are disposed; and
a cooling unit coupled with, and disposed between, the first memory die and the second memory die and comprising one or more conductive layers configured to dissipate heat, the cooling unit coupled with a first redistribution layer (RDL) that is coupled with the first substrate, and coupled with a second RDL that is coupled with the second substrate.
